(19) United States
(12) Patent Application Publication
(10) Pub. No.: US 2005/0133909 A1
(43) Pub. Date: Jun. 23, 2005

(54) Component packaging apparatus, systems, and methods

(75) Inventor: Luiz M. Franca-Neto, Portland, OR (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 10/739,468

(22) Filed: Dec. 18, 2003

(51) Int. Cl. H01L 23/34; H01L 21/48

(52) U.S. Cl. 257/724; 257/730; 438/107

(57) ABSTRACT

An apparatus and a system, as well as a method and an article, may include operating a processor included in a die having at least one scalable component of a circuit, including one or more radio frequency circuits, in electrical communication with a non-scalable component of the circuit located on a structure, such as a substrate or package to which the die may be coupled. The die may be constructed so that it does not include another non-scalable component of the circuit.

### RELATED APPLICATION

This disclosure is related to pending U.S. patent application Ser. No. ______, titled “Power Addition Apparatus, Systems, and Methods”, by Luiz M. Franca-Neto, filed on ______, and is assigned to the assignee of the embodiments disclosed herein, Intel Corporation.

### TECHNICAL FIELD

Various embodiments described herein relate to component packaging generally, including apparatus, systems, and methods used to package active and passive components.

### BACKGROUND INFORMATION

The task of integrating radio frequency (RF) circuitry, including transceivers, and digital circuitry, including microprocessors, on the same die presents at least two challenges. First, there may be a difference in signal levels between the two types of circuits of several orders of magnitude. Second, a conflict may arise between the die surface area consumed by the processor and that required by the RF circuitry, especially large passive components.

The first challenge may be evidenced when relatively small RF signals present at the antenna (e.g., tens of microvolts) are overwhelmed by substrate noise levels brought about by processor operation (e.g., tens or hundreds of millivolts). The second challenge may arise, for example, when relatively large inductors are used in the RF circuitry. Such inductors may not scale with the size of the digital circuitry, and thus, they may go counter to the increasing demand for smaller circuitry throughout the die.

### BRIEF DESCRIPTION OF THE DRAWINGS

FIG. 1 is a block diagram of an apparatus and a system according to various embodiments;

FIG. 2 is a top view of an apparatus and a system according to various embodiments;

FIGS. 3A and 3B are side views of a package and a die attached to a package, respectively, according to various embodiments;

FIGS. 4A and 4B are flow charts illustrating several methods according to various embodiments; and

FIG. 5 is a block diagram of an article according to various embodiments.

### DETAILED DESCRIPTION

Various embodiments disclosed herein address the challenges described above by moving inductors and other passive, non-scalable components typically found in RF circuitry, including RF and microwave transceivers, from the die, including a silicon die, to the package, including a flip-chip package. When this transition has been made, the passive, non-scalable components may realize higher performance, and size requirements may be more compatible with the available area.

In some embodiments of the invention, some or all of the passive components may be constructed using package traces, for example, including microstrip or stripline structures. This type of construction may even obviate the need for mounting discrete components on the package, making for a cost effective solution. In some embodiments, only active components, such as transistors, are left on the die, and thus full advantage of scaling may be taken with respect to all of the on-die components.

For the purposes of this document, a “scalable” component is a component of an electronic radio frequency circuit that is capable of being scaled in substantially direct proportion to transistors on the die as complementary metal-oxide semiconductor (CMOS) technology advances to offer transistors of shorter gate lengths without adversely affecting the performance of the radio frequency circuit which includes it, at least a portion of the radio frequency circuit being located on the die.

A “radio frequency circuit” includes a circuit that may be directly coupled to an antenna, and that operates to transmit and/or receive signals at the antenna having a magnitude ranging from about 0.1 microvolts to about 100 millivolts, over a frequency range of about 100 Hz to about 100 GHz.

An “active” component is a component of an electronic circuit, including a radio frequency circuit, that includes an element that provides power gain, such as a diode or a transistor. A “passive” component is a component of an electronic circuit, including a radio frequency circuit, that does not provide power gain, such as an inductor formed exclusively from metal, a conventional capacitor formed by placing metallic plates adjacent dielectric material, and a conventional carbon-film resistor, for example.

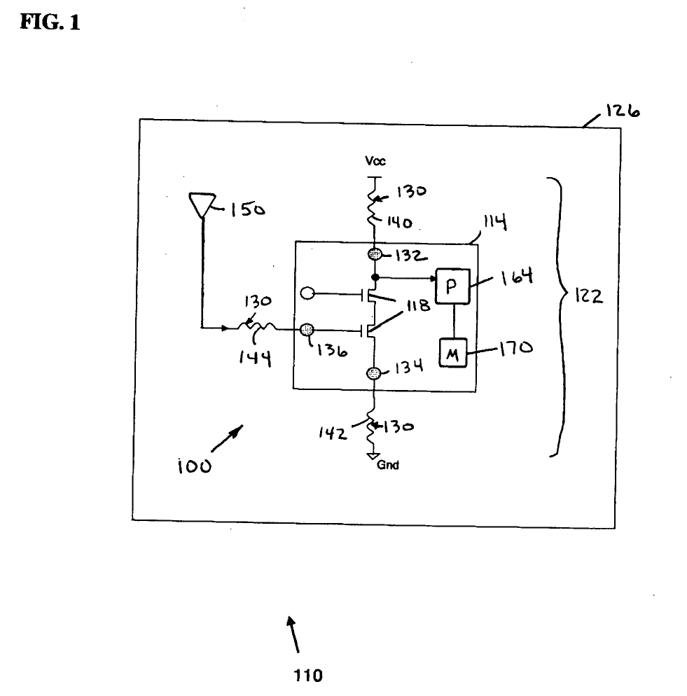

FIG. 1 is a block diagram of an apparatus 100 and a system 110 according to various embodiments, each of which may operate in the manner described above. In this case a generalized concept of several embodiments of the invention may be seen, wherein an apparatus 100 may include a die 114 having one or more scalable components 118 of a circuit 122, as well as a structure 126 having one or more non-scalable components 130 of the circuit 122. The die 114 may be fabricated so that it does not include any non-scalable components 130 of the circuit 122.

As a more specific exemplary embodiment, assume the circuit 122 includes a typical low noise amplifier (LNA). Non-scalable components 130 may include shunting passive components, such as area-hungry inductors, located on the structure 126, such as a package, including a flip-chip package. Power, ground, and RF signals may be routed from the external world to the LNA via nodes 132, 134, and 136, respectively, which may include controlled collapse chip connections.

Even though this particular example relates to LNA design, it should be noted that other functional blocks (e.g., voltage controlled oscillators, power amplifiers, mixers, synthesizers, etc.) of receivers, transmitters, and transceivers can be realized by coupling on-die, active scalable components 118, such as on-die transistors and diodes, with on-structure passive, non-scalable components 130, such as shunting inductors located on a structure 126, including a package attached to the die 114.

Thus, in some embodiments, an apparatus 100 may include a die 114 having at least one scalable component 118 of a circuit 122 and a structure 126 having at least one non-scalable component 130 of the circuit 122, wherein the die 114 does not include another non-scalable component 130 of the circuit 122. In some embodiments, the structure 126 may not include another scalable component 118 of the circuit 122. In some embodiments, the die 114 may be attached to the structure 126, perhaps using solder and/or one or more controlled collapse chip connections.

As noted previously, scalable components 118 may include one or more diodes and/or transistors, including FETs. Non-scalable components 130 may include one or more transformers, transmission lines, inductors, capacitors, and/or resistors, each of which may in turn include one or more traces (e.g., microstrip or striplines) forming a part of the structure 126. The circuit 122 may include one or more of a transceiver, a transmitter, a receiver, an amplifier, a synthesizer, an oscillator, and a mixer, among other RF circuit elements. The structure 126 may include a package, such as a flip-chip package.

Given the definitions of scalable and non-scalable components detailed previously, many embodiments may be realized. For example, an apparatus 100 may include a die 114 having a plurality of scalable components 118, including transistors forming a portion of a circuit 122, such as a radio frequency circuit. The apparatus may also include a package 126 having a plurality of non-scalable components 130 included in the circuit 122, such as a first inductor 140, wherein the die 114 does not include a second inductor 142 of the circuit 122. The plurality of non-scalable components 130 may include at least one of the second inductor 142 and a transformer 144 to couple one or more of the plurality of scalable components 118 to an antenna 150. The package 126 may include a flip-chip package, and the die 114 may be attached to the flip-chip package by one or more nodes 132, 134, 136, including controlled collapse chip connections. Still other embodiments may be realized.

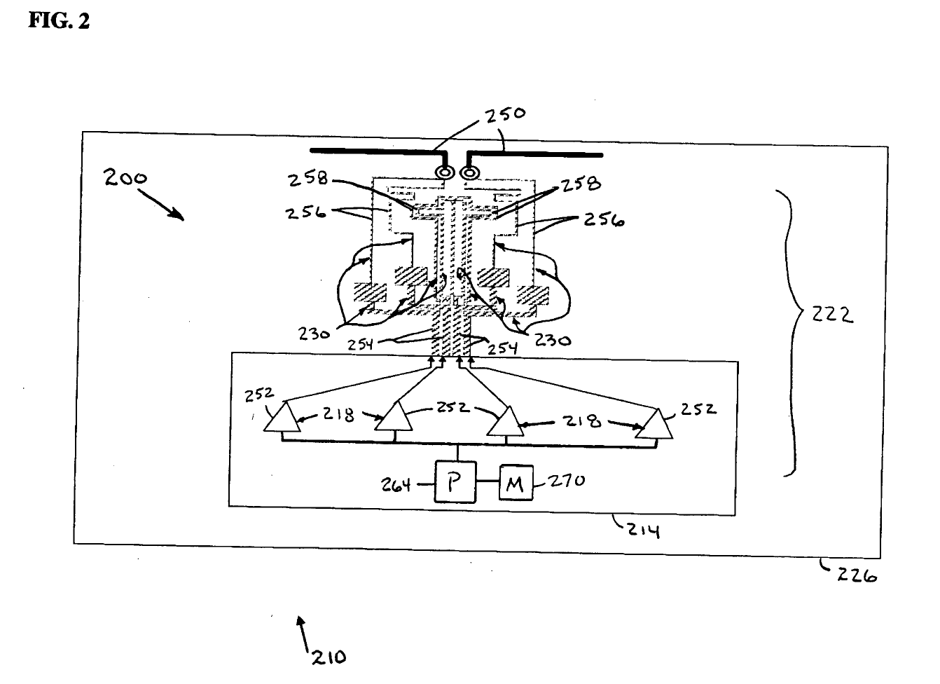

For example, FIG. 2 is a top view of an apparatus 200 and a system 210 according to various embodiments. The apparatus 200 and system 210 may be similar to or identical to the apparatus 100 and system 110 (see FIG. 1). In some embodiments, an apparatus 200 may include may include a die 214 having one or more scalable components 218 of a circuit 222, as well as a structure 226 having one or more non-scalable components 230 of the circuit 222. The die 214 may be fabricated so that it does not include any non-scalable components 230 of the circuit 222.

As a more specific exemplary embodiment, assume the circuit 222 includes a number of active scalable components, such as power amplifiers (PAs) 252. The non-scalable components 230 in this case may include passive components, such as impedance transformers 254, transmission lines 256, and RF chokes 258, each formed entirely using traces or microstrips on the structure 226, such as a package, including a flip-chip package.

In this example, the power output of the PAs 252 may be combined by using a series of passive, non-scalable components 230, enabling high-power RF transmission even though the PA design may be limited to a series of low-voltage transistors, such as complementary metal-oxide semiconductor (CMOS) devices. In some embodiments, a multi-band radio transceiver may be integrated on the same die with a general purpose processor, wherein all passive components, including passive non-scalable components, are located on the package. The general purpose processor may communicate with the radio transceiver through a memory buffer.

Still other embodiments may be realized. For example, referring to FIGS. 1 and 2, it can be seen that a system 110, 210 may include a die 114, 214 having a processor 164, 264 and one or more scalable components 118, 218 of a circuit 122, 222. The system 110, 210 may also include a structure 126, 226 having one or more non-scalable components 130, 230 of the circuit 122, 222. The die 114, 214 may be fabricated so as not to include another non-scalable component 130, 230 of the circuit 122, 222.

As noted previously, the structure 126, 226 may be formed so as not to include another scalable component 118, 218 of the circuit 122, 222. Scalable components 118, 218 may include power amplifiers, diodes, and/or transistors, among other elements. Non-scalable components 130, 230 may include transformers, transmission lines, inductors, capacitors, and resistors, among other elements. The die 114, 214 may be attached to the structure 126, 226. The circuit 122, 222 may include one or more RF circuits.

The system 110, 210 may include an antenna 150, 250, such as a monopole, dipole, patch, or omnidirectional antenna. The antenna 150, 250 may be directly coupled to the circuit 122, 222. The system 110, 210 may also include a memory 170, 270 coupled to the processor 164, 264, and the circuit 122, 222. The circuit 122, 222 may include one or more of a receiver, transmitter, and/or a transceiver, such as a data transceiver, and may form a portion of a cellular telephone. As an aid to understanding some of the embodiments, details of a potential packaging format will now be shown.

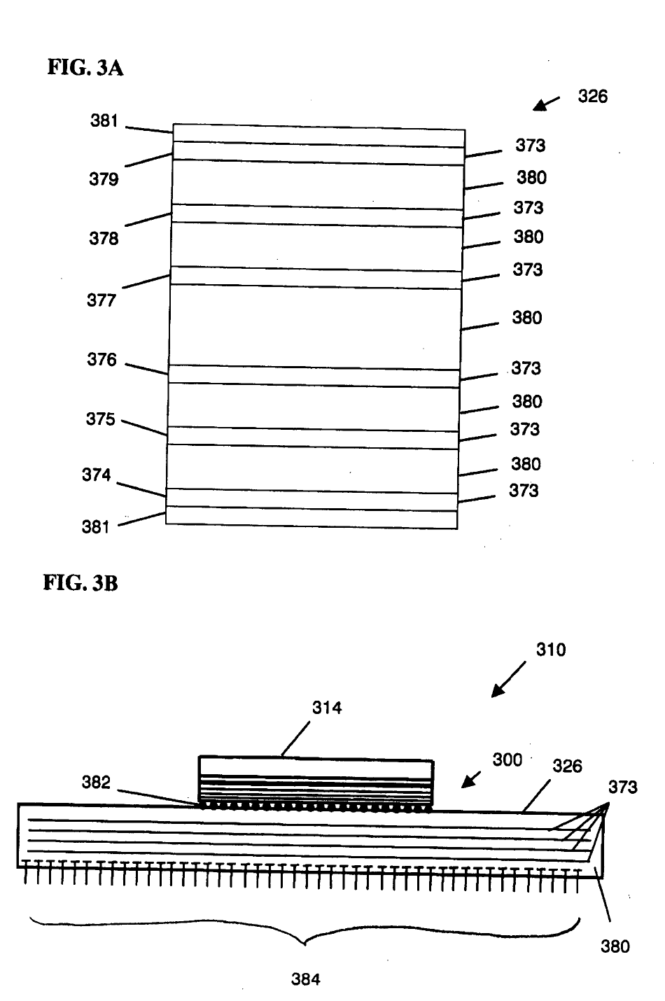

FIGS. 3A and 3B are side views of a package and a die attached to a package, respectively, according to various embodiments. As seen in FIG. 3A, the package 326 may include six conductor layers 373 (other numbers of layers are also possible). These conductor layers 373 may include a first power layer 374, a connection routing layer 375, a second power layer 376, a first RF trace layer 377, a ground plane layer 378, and a second RF trace layer 379, among others. Above, below, and between the conductor layers may be located dielectric layers 380 and solder mask layers 381.

Non-scalable components (not shown) may be included in the package 326, including on the first and second RF trace layers 377, 379. Nodes, similar to or identical to the nodes 132, 134, 136 (see FIG. 1) may be included in controlled collapse chip connections 382, and may be used to couple and/or attach the package 326 to the die 314, as shown in FIG. 3B. The die 314 and the package 326 may be used separately or together to implement various versions of the apparatus 300 and systems 310 (similar to or identical to the apparatus 100, 200 and systems 110, 210 shown in FIGS. 1 and 2, respectively) described herein. Package pins 384 may be used to couple the package 326 and die 314 circuitry to another circuit, such as a processor socket in a motherboard.

The apparatus 100, 200, 300, systems 110, 210, 310, dice 114, 214, 314, scalable components 118, 218, circuits 122, 222, structures 126, 226, 326, non-scalable components 130, 230, nodes 132, 134, 136, inductors 140, 142, transformer 144, antennas 150, 250, processors 164, 264, memories 170, 270, PAs 252, impedance transformers 254, transmission lines 256, RF chokes 258, conductor layers 373, power layers 374, 376, routing layer 375, RF trace layers 377, 379, dielectric layers 380, solder mask layers 381, and chip connections 382 may all be characterized as “modules” herein. Such modules may include hardware circuitry, and/or a processor and/or memory circuits, software program modules and objects, and/or firmware, and combinations thereof, as desired by the architect of the apparatus 100, 200, 300, and systems 110, 210, 310, and as appropriate for particular implementations of various embodiments. For example, such modules may be included in a system operation simulation package, such as a software electrical signal simulation package, a power usage and distribution simulation package, a capacitance-inductance simulation package, a power/heat dissipation simulation package, and/or a combination of software and hardware used to simulate the operation of various potential embodiments.

It should also be understood that the apparatus and systems of various embodiments can be used in applications other than for cellular telephones, and other than for systems that include wireless data communications, and thus, various embodiments are not to be so limited. The illustrations of apparatus 100, 200, 300 and systems 110, 210, 310 are intended to provide a general understanding of the structure of various embodiments, and they are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, processor modules, embedded processors, data switches, and application-specific modules, including multilayer, multi-chip modules. Such apparatus and systems may further be included as sub-components within a variety of electronic systems, such as televisions, cellular telephones, personal computers, workstations, radios, video players, vehicles, and others. Some embodiments include a number of methods.

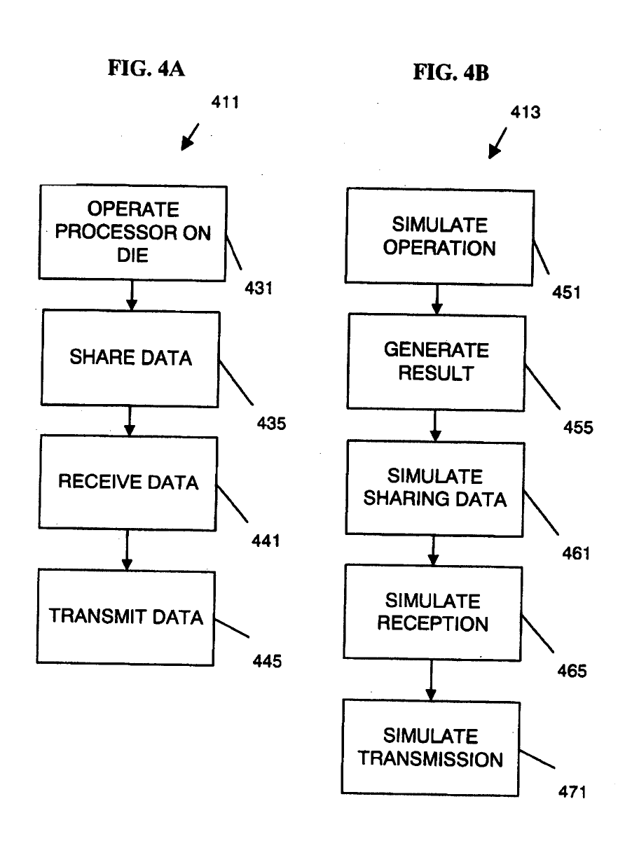

For example, FIGS. 4A and 4B are flow charts illustrating several methods 411, 413 according to various embodiments. For example, in some embodiments of the invention, a method 411 may (optionally) begin at block 431 with operating a processor included in a die having at least one scalable component of a circuit in electrical communication with a non-scalable component of the circuit (the die may be fabricated so as not to include another non-scalable component of the circuit, as noted previously). The method 411 may further include sharing data between the processor and the circuit at block 435, as well as receiving the data to store in a memory coupled to the processor at block 441, and transmitting the data stored in the memory coupled to the processor at block 445. Thus, in some embodiments, the circuit may include a data transceiver.

In some embodiments of the invention, a method 413 may include simulating the operation of a processor included in a die having at least one scalable component of a circuit in electrical communication with a non-scalable component of the circuit at block 451. Again, the die may be formed so as not to include another non-scalable component of the circuit. The method 413 may continue with generating a result of the simulating at block 455, including generating a human-perceivable result. Thus, the method 413 may include displaying a result of the simulation using a human-perceivable medium, such as a video display, or hardcopy printout.

As noted above, the die may comprise any number of circuits, including RF circuits, one or more processors and/or one or more memories. The result may therefore include an analysis of the noise levels present in the structure and/or die, especially with respect to operational signal levels present within the circuit, such as an RF circuit, and processors and/or memory that may be included on the die. The result may also include analyses directed toward power usage and efficiency, speed of operation, and sensitivity of various circuit parameters with respect to scaling of the scalable components on the die.

The method 413 may therefore include simulating sharing data between the processor and the circuit at block 461. The method 413 may also include simulating receiving the data to store in a memory coupled to the processor at block 465, as well as simulating transmitting the data stored in the memory coupled to the processor at block 471. As noted previously, the die may therefore include a processor coupled to the circuit, and the processor may operate to share data with the circuit.

It should be noted that the methods described herein do not have to be executed in the order described, or in any particular order. Moreover, various activities described with respect to the methods identified herein can be executed in serial or parallel fashion. Information, including parameters, commands, operands, and other data, can be sent and received in the form of one or more carrier waves.

Upon reading and comprehending the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java, Smalltalk, or C++. Alternatively, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment, including Hypertext Markup Language (HTML) and Extensible Markup Language (XML). Thus, other embodiments may be realized.

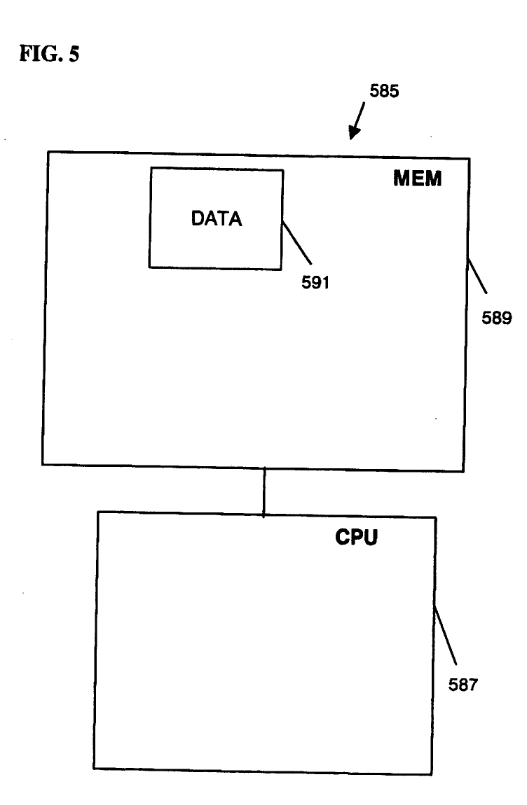

FIG. 5 is a block diagram of an article 585 according to various embodiments, such as a computer, a memory system, a magnetic or optical disk, some other storage device, and/or any type of electronic device or system. The article 585 may include a processor 587 coupled to a machine-accessible medium such as a memory 589 (e.g., a memory including an electrical, optical, or electromagnetic conductor) having associated information 591 (e.g., computer program instructions and/or data), which when accessed, results in a machine (e.g., the processor 587) performing such actions as simulating operating a processor included in a die having at least one scalable component of a circuit in electrical communication with a non-scalable component of the circuit, and generating a human-perceivable result of the simulating. Other activities may include simulating sharing data between the processor and the circuit simulating receiving the data to store in a memory coupled to the processor, and/or simulating transmitting the data stored in the memory coupled to the processor.

Improved integration of RF circuitry, including scalable portions of transceivers, and digital processors on the same die may result after implementing the apparatus, systems, and methods disclosed herein. Since some embodiments may have only transistors remaining on-die, the production of high-performance CMOS integrated radios may be realized, including fully-scalable dice forming part of a single package, such as a flip-chip package.

The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

1. An apparatus, including:
a die having at least one scalable component of a circuit; and
a structure having at least one non-scalable component of the circuit,
wherein the die does not include another non-scalable component of the circuit.

2. The apparatus of claim 1, wherein the structure does not include another scalable component of the circuit.

3. The apparatus of claim 1, wherein the die is attached to the structure.

4. The apparatus of claim 1, wherein the die is attached to the structure with at least one controlled collapse chip connection.

5. The apparatus of claim 1, wherein the scalable component includes a transistor.

6. The apparatus of claim 1, wherein the structure includes a flip-chip package.

7. The apparatus of claim 1, wherein the at least one non-scalable component includes at least one of a transformer, a transmission line, an inductor, a capacitor, and a resistor.

8. The apparatus of claim 1, wherein the circuit includes at least one of a transceiver, a transmitter, a receiver, an amplifier, a synthesizer, an oscillator, and a mixer.

9. The apparatus of claim 1, wherein the at least one non-scalable component includes a trace included in the structure.

10. The apparatus of claim 9, wherein the trace is included in at least one of a transmission line, an inductor, and a transformer.

11. An apparatus, including:
a die having a plurality of scalable transistors included in a radio frequency circuit; and
a package having a plurality of non-scalable components included in the radio frequency circuit, including a first inductor, wherein the die does not include a second inductor of the radio frequency circuit.

12. The apparatus of claim 11, wherein the plurality of non-scalable components include at least one of a second inductor, and a transformer to couple at least one of the plurality of scalable transistors to an antenna.

13. The apparatus of claim 12, wherein the package includes a flip-chip package, and wherein the die is attached to the flip-chip package by a controlled collapse chip connection.

14. A system, including:
a die having a processor and at least one scalable component of a circuit; and
a structure having at least one non-scalable component of the circuit,
wherein the die does not include another non-scalable component of the circuit.

15. The system of claim 14, further including:
a dipole antenna to couple to the circuit.

16. The system of claim 14, wherein the structure does not include another scalable component of the circuit.

17. The system of claim 14, wherein the die is attached to the structure.

18. The system of claim 14, wherein the scalable component includes a transistor.

19. The system of claim 14, wherein the at least one non-scalable component includes at least one of a transformer, a transmission line, an inductor, a capacitor, and a resistor.

20. The system of claim 14, wherein the circuit includes a radio frequency circuit.

21. The system of claim 14, further including:
a memory coupled to the processor and the circuit, wherein the circuit includes a data transceiver.

22. A method, including:
operating a processor included in a die having at least one scalable component of a circuit in electrical communication with a non-scalable component of the circuit, wherein the die does not include another non-scalable component of the circuit.

23. The method of claim 22, further including:
sharing data between the processor and the circuit.

24. The method of claim 23, further including:
receiving the data to store in a memory coupled to the processor.

25. The method of claim 23, further including:
transmitting the data stored in a memory coupled to the processor.

26. The method of claim 22, wherein the circuit includes a data transceiver.

27. An article comprising a machine-accessible medium having associated information, wherein the information, when accessed, results in a machine performing:
simulating operating a processor included in a die having at least one scalable component of a circuit in electrical communication with a non-scalable component of the circuit, wherein the die does not include another non-scalable component of the circuit; and
generating a human-perceivable result of the simulating.

28. The article of claim 27, wherein the die includes a processor coupled to the circuit.

29. The article of claim 28, wherein the processor is to share data with the circuit.

30. The article of claim 27, wherein the information, when accessed, results in the machine performing:
simulating sharing data between the processor and the circuit including a data transceiver.

31. The article of claim 30, wherein the information, when accessed, results in the machine performing:
simulating receiving the data to store in a memory coupled to the processor.

32. The article of claim 30, wherein the information, when accessed, results in the machine performing:
simulating transmitting the data stored in a memory coupled to the processor.
